(19) United States
(12) Patent Application Publication
(10) Pub. No.: US 2014/0150826 A1
(43) Pub. Date: Jun. 5, 2014

(54) WAFER CLEANING APPARATUS AND METHODS

(71) Applicant: MEMC Singapore Pte. Ltd. (UEN200614794D), Singapore (SG)

(72) Inventors: Peter D. Albrecht, O'Fallon, MO (US); Brian Schulte, Wentzville, MO (US); Vandan Tanna, Dardenne Prairie, MO (US); Terry Grace, Ellisville, MO (US); Desmond Teo, Kuching (MY); Fu Shun Ng, Kuching (MY)

(21) Appl. No.: 14/092,370

(22) Filed: Nov. 27, 2013

Related U.S. Application Data
(60) Provisional application No. 61/732,007, filed on Nov. 30, 2012.

(51) Int. Cl. H01L 21/67

(52) U.S. Cl. CPC H01L 21/67057
USPC 134/25.5; 134/184; 134/186

(57) ABSTRACT

A wafer cleaning apparatus includes a beam for holding a plurality of semiconductor or solar wafers. The beam includes at least one channel extending axially through the beam. An opening extends from the channel to a location between adjacent wafers. A manifold includes a conduit coupled to the channel and an immersion tank includes an ultrasonic transducer.

### CROSS-REFERENCE TO RELATED APPLICATION

This application claims priority to U.S. Provisional Application No. 61/732,007 filed on Nov. 30, 2012, which is hereby incorporated by reference in its entirety.

### FIELD

The field relates generally to apparatus and methods for cleaning silicon wafers, and more particularly to apparatus and methods for removing debris from semiconductor or solar wafers using an ultrasonic cleaning apparatus.

### BACKGROUND

Semiconductor or solar wafers are generally prepared from an ingot (e.g., a silicon ingot) which is trimmed and ground to have one or more flats or notches for proper orientation of the wafer in subsequent procedures. Wafers used for semiconductors and solar cells are typically cut with a wire saw from an ingot made of silicon, sapphire, germanium or the like. Typically the ingot is attached to a sacrificial beam by an adhesive such as epoxy. The wire saw cuts the ingot by contacting the ingot with a wire coated with an abrasive or covered in an abrasive slurry. The abrasive slurry typically includes a fine abrasive, such as silicon carbide (SiC) or an industrial diamond suspended in a liquid suspension medium, or the abrasive is bonded to the wire.

In operation, the ingot is cut by applying force to the wire to press the wire, and thereby the abrasive particles, against the ingot. The abrasive slurry is drawn in between the wire and the ingot during movement of the wire and thereby abrades the ingot and removes fine particles, chips, or shavings (collectively referred to as “swarf”) from the ingot. Most of the fine particles are carried away from the interface of the wire and the ingot by the abrasive slurry or a cutting fluid.

During use, the wire and wafers become coated with swarf and/or other contaminants. Typically, the wafers are close together and relatively flexible while supported by the beam. As such, lower surfaces of the wafers may stick together due to surface tension from the liquid used to cool the wire saw or the rinsing liquid. It is therefore difficult to adequately clean between the surfaces of the wafers, and the uncleaned surfaces may result in the formation of a stain in the area where the wafers stuck together.

In order to clean the area between the wafers, a lance that is the length of the sacrificial beam is inserted into holes formed in the sacrificial beam. The lance is moved in and out, while liquid is supplied from an outlet formed at a distal end of the lance. Alternatively, the lance is held stationary but the sacrificial beam, together with the wafers, is moved back and forth. In either case, the flow from the lance is concentrated in a small area that moves from one end of the beam to the other, which causes a very forceful flow of liquid between the wafers. However, it has been found that much of the swarf remains stuck to the wafers and is not thoroughly cleaned using such known methods.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF DESCRIPTION

A first aspect of the present disclosure is a wafer cleaning apparatus. The apparatus includes a beam for supporting a plurality of semiconductor wafers, at least one channel extending axially through the beam, an opening extending from the channel to a location between adjacent wafers, a manifold, and an immersion tank. The manifold includes a conduit for facilitating liquid flow through the opening. The immersion tank includes an ultrasonic transducer, and is sized to receive at least a pair of adjacent wafers.

Another aspect of the present disclosure is a method of removing contaminants from a pair of adjacent wafers bonded to a sacrificial beam. The method includes coupling a manifold to the sacrificial beam such that a fluid conduit of the manifold is in fluid communication with a channel that extends axially through the sacrificial beam, submerging the wafers in a liquid contained in an immersion tank, the immersion tank including an ultrasonic transducer, flowing the liquid through the manifold such that the liquid flows through the channel and an inter-wafer opening, and contacts the wafers, and operating the ultrasonic transducer to induce vibrations within the immersion tank.

### BRIEF DESCRIPTION OF THE DRAWINGS

FIG. 1 is a perspective of an embodiment of a wafer cleaning apparatus.

FIG. 2 is a perspective of an embodiment of a manifold and sacrificial beam of a wafer cleaning apparatus.

FIG. 3 is a section showing an embodiment of a sacrificial beam and wafer of a wafer cleaning apparatus.

FIG. 4 is a side elevation of an embodiment.

Corresponding reference characters indicate corresponding parts throughout the drawings.

### DETAILED DESCRIPTION

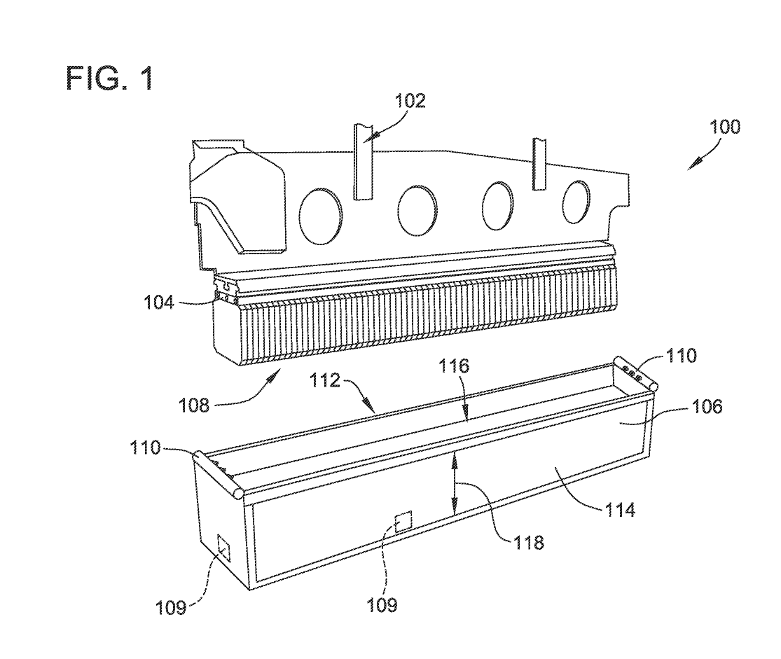

FIG. 1 shows a perspective of an embodiment of a wafer cleaning apparatus 100. The wafer cleaning apparatus includes a lift 102 coupled to a sacrificial beam 104. In some embodiments, the wafer cleaning apparatus includes an immersion tank 106, which may include one or more ultrasonic transducers 109. In this embodiment, a plurality of semiconductor wafers 108 are coupled (i.e., hanging) from sacrificial beam 104. In some embodiments, the plurality of semiconductors may include one hundred or more wafers, or one thousand or more wafers. A manifold 110 is disposed near an end of the immersion tank 106.

Lift 102 is configured to be mechanically coupled to sacrificial beam 104 by way of fasteners, adhesives or the like. Lift 102 is operable to raise, lower, translate or rotate in order to align wafers 108 such that they may be placed within immersion tank 106.

In this embodiment, immersion tank 106 has an open box shape with a rectangular cross section. The immersion tank 106 includes an open top 112 and an opposed closed bottom. Sidewalls 114 intersect the closed bottom to define an interior 116 of tank 106. In this embodiment, interior 116 is sized to accommodate all of the wafers 108 coupled to sacrificial beam 104. However, in other embodiments, interior 116 is sized to accommodate at least one pair of adjacent wafers 108. The immersion tank 106 is configured to be substantially fluid tight, such that a quantity of liquid, such as a cleaning fluid, at least partially fills the interior 116. In some embodiments, the height 118 of immersion tank 106 is sufficiently tall that wafers 108 fit entirely within the interior 116 and are completely submerged in the liquid. However, the height 118 of the immersion tank may be any height such that the cleaning apparatus functions as described herein. In one embodiment, the cleaning fluid is water. In other embodiments, the cleaning fluid is a water solution containing one or more surfactants.

In one embodiment, an ultrasonic transducer 109 is coupled to the bottom and/or sidewalls 114 of immersion tank 106. The ultrasonic transducers 109 are configured to vibrate at a predetermined frequency, such as from about 30 kHz to about 80 kHz, at a power such as from about 50 Watts to 1500 Watts. However, the frequency and power of the ultrasonic transducers may be other values that allow the system to function as described herein. In use, the vibrations from the ultrasonic transducers are transmitted to the liquid within the interior 116 of the immersion tank 106, and subsequently to any wafers 108 disposed within the interior 116.

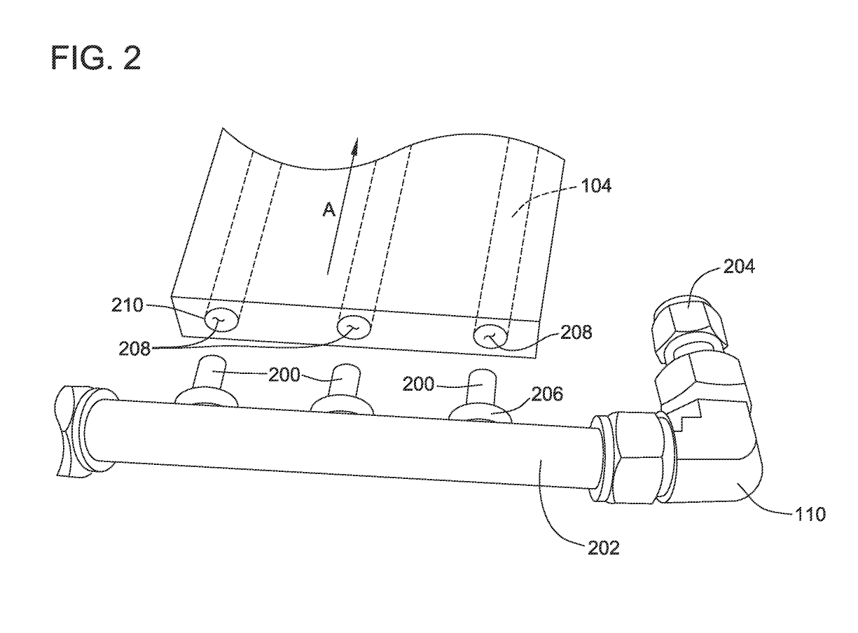

FIG. 2 shows a perspective of a manifold 110. As shown, manifold 110 is adjacent a sacrificial beam 104, and is shown without wafers 108 or other components of the cleaning apparatus 100 for clarity. Manifold 110 includes at least one conduit 200 that is in fluid communication with a main fluid distribution portion 202. Manifold 110 also includes at least one fluid inlet 204 for supplying a flow of liquid through manifold 110. In one embodiment, manifold 110 includes a seal 206, such as a gasket or the like. Seal 206 is configured to provide a liquid tight seal of conduit 200 to sacrificial beam 104 when in use.

In this embodiment, sacrificial beam 104 includes a channel 208 (e.g., a hole) that extends along an axial direction A of sacrificial beam 104. As shown, a rim 210 defines an outer perimeter of channel 208. Each channel 208 has an inside diameter sized to accommodate a corresponding conduit 200. In use, conduit 200 is placed at least partially within opening 208 to enable fluid communication from manifold 110 through sacrificial beam 104. In one embodiment, manifold 110 is biased against rim 210 such that seals 206 form a substantially fluid tight seal with sacrificial beam 104.

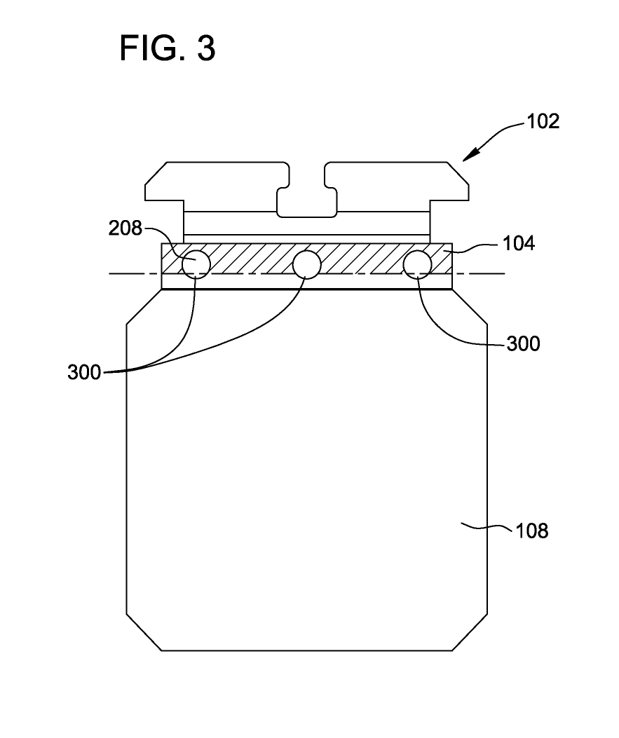

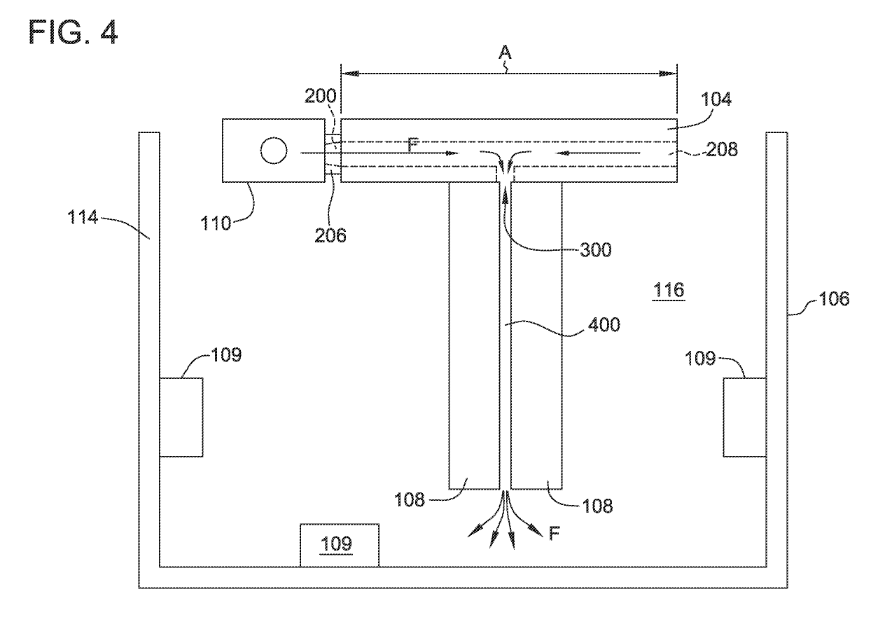

Reference is now made to FIGS. 3 and 4. A wafer 108 is coupled to sacrificial beam 104 at an upper surface thereof, for example by way of an adhesive. An inter-wafer opening 300 is located between adjacent wafers 108. Inter-wafer opening 300 is open on a lower side thereof to a space 400 between the adjacent wafers. In one embodiment, inter-wafer opening 300 has an elongated (i.e., slot) shape that is formed during a wafer cutting operation, by a wire saw cutting into the sacrificial beam 104. For example, a wire saw (not shown) may be used to slice a semiconductor ingot into wafers 108 by cutting through the ingot, and partially into the sacrificial beam 104, and into channel 208 thus forming the inter-wafer opening 300.

In operation, wafers 108 are lowered or otherwise placed within interior 116 of immersion tank 106. Manifold 110 is biased against the sacrificial beam 104 such that the conduit 200 is in fluid communication with channel 208. In one embodiment, conduit 200 remains stationary within channel 208 during the subsequent operations. A liquid, such as a cleaning fluid, flows from manifold 110 in the direction of arrows F. The liquid flows through conduit 200 and through channel 208. The liquid exits channel 208 through the inter-wafer opening(s) 300 after flowing through channel 208.

The liquid exiting the inter-wafer openings 300 flows against the wafers 108 in space 400 to wash away swarf or other debris adhered to wafers 108 within space 400. In some embodiments, the ultrasonic transducers 109 are operated before, or during, the liquid being pumped through the manifold 110. As such, the ultrasonic transducers 109 transmit vibrations to the wafers 108 such that swarf and debris are loosened therefrom, and the liquid entrains the loosened debris within the liquid flow. In addition, the liquid flow through space 400 may separate adjacent wafers 108 from each other, if previously stuck together. Although FIG. 4 shows only a single manifold 110, a second manifold may be placed on an opposite side of sacrificial beam 104 to supply liquid in counterflow through a second conduit into channel 208. In yet other embodiments, additional manifolds may be used to supply liquid to channel 208. Although FIG. 3 shows three channels 208, any number of channels 208 may be used that allows the cleaning apparatus to function as described herein.

In some embodiments, the liquid flow is controlled to be between about 15 liters per minute to about 50 liters per minute. However, other flow rates may be used that enable the cleaning apparatus to function as described herein.

In one embodiment, a total combined length of the inter-wafer openings extends approximately 30 percent to 50 percent of the length of the channel 208. For example, in one embodiment, each inter-wafer opening has an axial length which corresponds to the diameter of the wire of the wire saw used to cut the openings. In one embodiment, for example, each inter-wafer opening has an axial length of approximately 160 micrometers, and a transverse (i.e., perpendicular to the axial direction) width of approximately 8.5 millimeters. In this embodiment, each channel 208 has a diameter of approximately 12 millimeters. In another embodiment, the total open area of the inter-wafer openings is between 15 times to 20 times the cross-sectional area of the channel 208. However, these areas, lengths and widths may be of any size that allow the cleaning apparatus to function as described herein.

This disclosure generally provides improved apparatus and methods for cleaning debris from a semiconductor or solar wafer. These result in a less complex apparatus and method as compared to existing systems. For example, the prior art full length lances, and the complexity of moving these lances, is eliminated by the improved design.

When introducing elements of the present invention or the embodiment(s) thereof, the articles “a”, “an”, “the” and “said” are intended to mean that there are one or more of the elements. The terms “comprising”, “including” and “having” are intended to be inclusive and mean that there may be additional elements other than the listed elements. The use of terms indicating a particular orientation (e.g., “top”, “bottom”, “side”, etc.) is for convenience of description and does not require any particular orientation of the item described.

As various changes could be made in the above without departing from the scope of the invention, it is intended that all matter contained in the above description and shown in the accompanying drawings shall be interpreted as illustrative and not in a limiting sense.

What is claimed is:

1. A wafer cleaning apparatus, comprising:
a beam for supporting a plurality of semiconductor wafers, the beam including at least one channel extending axially through the beam;
an opening extending from the channel to a location between adjacent wafers;
a manifold including a conduit for facilitating liquid flow through the opening; and
an immersion tank including an ultrasonic transducer, the immersion tank sized to receive at least a pair of adjacent wafers.

2. The apparatus according to claim 1, wherein the immersion tank is sized such that the wafers are completely submergible in a cleaning solution contained within the immersion tank.

3. The apparatus according to claim 1, further comprising a second manifold including a second conduit sealingly coupled to a second channel located at an opposite axial end of the sacrificial beam from the channel.

4. The apparatus according to claim 1, wherein the conduit is fixedly coupled to a rim defining an outer perimeter of the channel.

5. The apparatus according to claim 1, further comprising a liquid pump configured to supply a flow of liquid through the manifold and into the channel.

6. The apparatus according to claim 5, wherein the pump is configured to supply between 15 liters per minute to 50 liters per minute of liquid flow per manifold.

7. The apparatus according to claim 1, comprising a plurality of openings, wherein a combined area of the openings is approximately 15 times to 20 times greater than a cross-sectional area of the channel.

8. The apparatus according to claim 1, wherein the opening is a slot extending transverse to the channel.

9. The apparatus according to claim 1, comprising at least three channels.

10. The apparatus according to claim 9, wherein the opening is in flow communication with each of the at least three channels.

11. The apparatus according to claim 1, wherein the immersion tank includes a bottom wall and a sidewall, and the ultrasonic transducer is coupled to the bottom wall and a second ultrasonic transducer is coupled to the sidewall.

12. The apparatus according to claim 11, wherein each ultrasonic transducer is operational from about 50 Watts to 1500 Watts and from about 30 kHz to about 80 kHz.

13. The apparatus according to claim 1, wherein the conduit has a length that is less than the axial length of the channel.

14. The apparatus according to claim 1, wherein the beam is a sacrificial beam coupled to a plurality of semiconductor wafers.

15. A method of removing contaminants from a pair of adjacent wafers bonded to a sacrificial beam, the method comprising:
coupling a manifold to the sacrificial beam such that a fluid conduit of the manifold is in fluid communication with a channel that extends axially through the sacrificial beam;
submerging the wafers in a liquid contained in an immersion tank, the immersion tank including an ultrasonic transducer;
flowing the liquid through the manifold such that the liquid flows through the channel and an inter-wafer opening, and contacts the wafers; and
operating the ultrasonic transducer to induce vibrations within the immersion tank.

16. The method according to claim 15, wherein flowing the liquid includes flowing between 15 liters per minute to 50 liters per minute of liquid.

17. The method according to claim 15, further comprising maintaining the conduit in a stationary position during the flowing of the liquid.

18. The method according to claim 15, further comprising operating the ultrasonic transducer at from about 50 Watts to 1500 Watts and from about 30 kHz to 80 kHz.

19. The method according to claim 15, wherein operating the ultrasonic transducer loosens debris on the semiconductor wafers and flowing the liquid through the inter-wafer opening carries the debris off of the wafers by entraining the debris in the liquid.

20. The method according to claim 15, further comprising coupling a second manifold to the sacrificial beam such that a second fluid conduit of the second manifold is in flow communication with an end of the channel opposite the other conduit.

21. The method according to claim 20, wherein flowing the liquid includes flowing the liquid through the second manifold.
